(19) United States
(12) Patent Application Publication
(10) Pub. No.: US 2007/0120606 A1
(43) Pub. Date: May 31, 2007

(54) Base station power amplifier for memory effect minimization

(75) Inventors: Jong-Sung Lee, Yongin-si (KR); Keun-Hyo Song, Seongnam-si (KR); Han-Seok Kim, Seoul (KR); Sei-Jei Cho, Seoul (KR); Joong-Ho Jeong, Seoul (KR); Bumman Kim, Pohang-si (KR); Jeonghyeon Cha, Pohang-si (KR)

Correspondence Address: DILWORTH & BARRESE, LLP, 333 EARLE OVINGTON BLVD., SUITE 702, UNIONDALE, NY, 11553, US

(73) Assignees: SAMSUNG ELECTGRONICS CO., LTD., Suwon-si (KR); POSTECH ACADEMY-INDUSTRY FOUNDATION, Pohang-si (KR)

(21) Appl. No.: 11/598,589

(22) Filed: Nov. 13, 2006

(30) Foreign Application Priority Data
Nov. 12, 2005 (KR) 2005-0108278

(51) Int. Cl. H03F 3/191

(52) U.S. Cl. 330/302

(57) ABSTRACT

A base station power amplifier for minimizing memory effect is provided. The power amplifier includes a bias circuit which supplies a direct current (DC) power to a transistor; the transistor which amplifies the DC power provided from the bias circuit; a matching circuit which transfers maximum power to a load by reducing loss of the power amplified by the transistor; and a large capacitor which lies between the matching circuit and the transistor, reduces a low-frequency second harmonic voltage by electrically connecting directly to the matching circuit, and has a preset capacitance value.

### PRIORITY

This application claims priority under 35 U.S.C. § 119 to an application filed in the Korean Intellectual Property Office on Nov. 12, 2005 and assigned Serial No. 2005-108278, the contents of which are incorporated herein by reference.

### BACKGROUND OF THE INVENTION

1. Field of the Invention

The present invention relates generally to a power amplifier, and in particular, to a linear amplification power amplifier for a broadband signal with minimal memory effect of the mobile communication base station/repeater.

2. Description of the Related Art

Memory effects relative to the nonlinearity of an amplifier are produced by a very complicated non-linear mechanism. When a simplified model is used, these effects can be expressed as the following Equation 1, which refers to “J. Vuolevi and T. Rahkonen, Distortion in RF Power Amplifiers. Norwood, Ma.: Artech House, 1999.”

Since a transistor is quite a non-linear element, the gate voltage and the drain voltage are expressed as the sum of voltages with respect to various frequency ranges. Equation 1 is also quite intricate. Thus, the non-linearity of the amplifier can be acquired by extracting only the component for Third order Inter-Modulation Distortion (IMD3) signal expressed as Equation 1 and Equation 2.

$$Equation 1 \text{:}$$

$$\begin{matrix}{i}_{d} = {g}_{m} \cdot {v}_{gs} + {K}_{{2}_{gm}} \cdot {v}_{gs}^{2} + {K}_{{3}_{gm}} \cdot {v}_{gs}^{3} + \\ {g}_{o} \cdot {v}_{ds} + {K}_{{2}_{go}} \cdot {v}_{ds}^{2} + {K}_{{3}_{go}} \cdot {v}_{ds}^{3} + \\ {K}_{{2}_{gm \& go}} \cdot {v}_{gs} \cdot {v}_{ds} + \\ {K}_{{3}_{2 gm \& go}} \cdot {v}_{gs}^{2} \cdot {v}_{ds} + {K}_{{3}_{gm \& 2 go}} \cdot {v}_{gs} \cdot {v}_{ds}^{2}\end{matrix}$$

$$Equation 2 \text{:}$$

$$\begin{matrix}{i}_{d} ( 2 {w}_{2} - {w}_{1} ) = {g}_{m} \cdot {v}_{gs} ( 2 {w}_{2} - {w}_{1} ) + \\ {K}_{{2}_{gm}} \cdot {v}_{gs} ( {w}_{1} ) \cdot {v}_{gs} ( 2 {w}_{2} ) + \\ {K}_{{2}_{gm}} \cdot {v}_{gs} ( {w}_{2} ) \cdot {v}_{gs} ( {w}_{2} - {w}_{1} ) + \\ 3 / 4 \cdot {K}_{{3}_{gm}} \cdot {v}_{gs} ( {w}_{1} ) \cdot {v}_{gs}^{2} ( {w}_{2} ) + \\ {g}_{o} \cdot {v}_{ds} ( 2 {w}_{2} - {w}_{1} ) + \\ {K}_{{2}_{go}} \cdot {v}_{ds} ( {w}_{1} ) \cdot {v}_{ds} ( 2 {w}_{2} ) + \\ {K}_{{2}_{go}} \cdot {v}_{ds} ( {w}_{2} ) \cdot {v}_{ds} ( {w}_{2} - {w}_{1} ) + \\ 3 / 4 \cdot {K}_{{3}_{go}} \cdot {v}_{ds} ( {w}_{1} ) \cdot {v}_{ds}^{2} ( {w}_{2} ) + \\ {K}_{{2}_{gm \& go}} \cdot {v}_{gs} ( {w}_{1} ) \cdot {v}_{ds} ( 2 {w}_{2} ) + \\ {K}_{{2}_{gm \& go}} \cdot {v}_{ds} ( {w}_{1} ) \cdot {v}_{gs} ( 2 {w}_{2} ) + \\ {K}_{{2}_{gm \& go}} \cdot {v}_{gs} ( {w}_{1} ) \cdot {v}_{ds} ( {w}_{2} - {w}_{1} ) + \\ {K}_{{2}_{gm \& go}} \cdot {v}_{ds} ( {w}_{1} ) \cdot {v}_{gs} ( {w}_{2} - {w}_{1} ) + \\ 3 / 4 \cdot {K}_{{3}_{gm \& go}} \cdot {v}_{ds} ( {w}_{1} ) \cdot {v}_{gs}^{2} ( {w}_{2} ) + \\ 3 / 4 \cdot {K}_{{3}_{gm \& 2 go}} \cdot {v}_{gs} ( {w}_{1} ) \cdot {v}_{ds}^{2} ( {w}_{2} )\end{matrix}$$

Equation 2 is the mathematical expression of the IMD3 current to the FET transistor. gₘ, K₂_{_{gm}}, K₃_{_{gm}}, gₒ, K₂_{_{go}}, K₃_{_{go}}, K₂_{_{gm&go}}, K₃_{_{2gm&go}}, and K₃_{_{gm&2go}} are constants to determine the characteristic of the transistor. V_{gs} and V_{ds}, denote the voltage applied to the gate and the voltage applied to the drain, respectively. The items in parentheses represent the frequency component. As Equation 2 decreases, the amplifier operates linearly. The minimization of this value is the aim of the amplifier designer. However, the designer cannot change nine constants which determine the characteristic of the transistor, and cannot control the frequency dependent voltages w₁ and w₂ because those voltages have fixed values for the design of an optimum power amplifier. Additionally, although the component 2 w₂-w₁ has to be the controllable item in theory, it is almost impossible to control it because w₁ or w₂ is very close to the resonant frequency of the component. Yet, this item is not so problematic because a predistortion linearizer can easily eliminate it. By contrast, the non-linearity exhibited by the second harmonic voltage (items 2 w₂ and w₂-w₁) is not easily eliminated by the predistortion linearizer because it causes memory effect. The memory effect is a phenomenon where a previous signal temporally affects the current non-linearity and thus changes the magnitude or phase of the original non-linear component. As for the greater value of the low-frequency second harmonic (w₂-w₁), which indicates the bandwidth of the signal, it is very difficult to reduce the corresponding voltage (or impedance) to zero. Thus, the considerable memory effect and signal non-linearity are inevitable. Meanwhile, the high-frequency second harmonic voltage (2 w₂) is easily controllable to zero and scarcely affects the memory effect comparing to the low-frequency second harmonic voltage. Hence, the high-frequency second harmonic voltage (2 w₂) can be disregarded.

FIG. 1 illustrates a circuit of a conventional base station/repeater power amplifier. In the design phase, the power amplifier is largely divided into a signal matching circuit 100 and a bias circuit 200. The matching circuit has a matching circuit 101 to transfer the maximum power to a load, and the bias circuit supplies DC power for the amplification of the amplifier. Typically, the DC power is supplied through the transmission line. Therefore, in order not to affect the signal matching circuit 100 and to eliminate the second harmonic voltage affecting the non-linear characteristic of the transistor, appropriate capacitors 201 and 202 are attached to the quarter wavelength (λ/4) position with respect to the signal frequency. Capacitors 201 and 202 become an open circuit, which passes only the second harmonic component to ground and does not pass the other components. A bias configuration including capacitor 201 is depicted in FIG. 2 as below.

FIG. 2 depicts an equivalent circuit of the bias circuit configuration of the conventional power amplifier.

The above described power amplifier is used today in application fields using relatively narrowband signals. Yet, the voltage component w₂-w₁ may still be present in the broadband signal because of the unique impedance of the λ/4 bias line. Therefore, it is hard to apply such a power amplifier to a next-generation application, which requires the broadband signal amplification. For reference, a capacitor 102 of the signal matching circuit 100 is attached to supply the DC current merely to the transistor.

The general power amplifier of FIG. 1 can linearly amplify the 20 MHz bandwidth signal or so through the optimization of the bias circuit 200, but cannot address the memory effect which is another important property of the power amplifier. Mainly the low-frequency second harmonic voltage causes the memory effect. The general power amplifier of the related art suffers limitation in eliminating the harmonic voltage by the bias line. This limitation considerably restricts the performance of the linearizer used in most of the base station/repeater power amplifier systems. Therefore, what is demanded is a new configuration of the power amplifier, which can minimize the memory effect and linearly amplify the signals of wider bandwidth.

### SUMMARY OF THE INVENTION

An aspect of the present invention is to substantially solve at least the above problems and/or disadvantages and to provide at least the advantages below. Accordingly, an aspect of the present invention is to provide a power amplifier for linear amplification of a broadband signal with minimized memory effect of the linear power amplifier.

Another aspect of the present invention is to provide a power amplifier, which decreases the low-frequency second harmonic voltage by electrically connecting a capacitor directly to a matching circuit of the power amplifier.

A further aspect of the present invention is to provide a power amplifier, which decreases the low-frequency second harmonic voltage by electrically connecting a capacitor directly to a matching circuit of the power amplifier and resonating the parasitic inductance component in the capacitor and the matching circuit.

The above aspects are achieved by providing a power amplifier including a bias circuit which supplies a direct current (DC) power to a transistor; a transistor which amplifies the DC power provided from the bias circuit; a matching circuit which transfers the maximum power to a load by reducing loss of the power amplified by the transistor; and a large capacitor which lies between the matching circuit and the transistor, reducing the low-frequency second harmonic voltage by electrically connecting directly to the matching circuit, which has a preset capacitance value.

### BRIEF DESCRIPTION OF THE DRAWINGS

The above and other objects, features and advantages of the present invention will become more apparent from the following detailed description when taken in conjunction with the accompanying drawings in which:

FIG. 1 illustrates a circuit configuration of a conventional base station/repeater power amplifier;

FIG. 2 illustrates an equivalent circuit of a bias circuit configuration of the conventional power amplifier;

FIG. 3 illustrates a base station power amplifier, which minimizes memory effect according to the present invention;

FIG. 4 is a circuit diagram of the base station power amplifier, which minimizes the memory effect according to the present invention;

FIG. 5 illustrates the impedance change of the low-frequency second harmonic component according to the signal bandwidth of the conventional power amplifier and the power amplifier of the present invention in a Smith chart;

FIG. 6A illustrates IMD3 non-linear characteristic when a 2-tone signal is applied to the conventional power amplifier;

FIG. 6B illustrates IMD3 non-linear characteristic when a 2-tone signal is applied to the power amplifier according to the present invention;

FIG. 7A illustrates output spectrums of the conventional power amplifier and the power amplifier of the present invention at WCDMA 4FA 20 MHz signal;

FIG. 7B illustrates output spectrums of the conventional power amplifier and the power amplifier of the present invention at WCDMA 20FA 100 MHz signal; and

FIG. 8 illustrates linearization performance when a predistortion linearizer is attached to the conventional power amplifier and the power amplifier of the present invention.

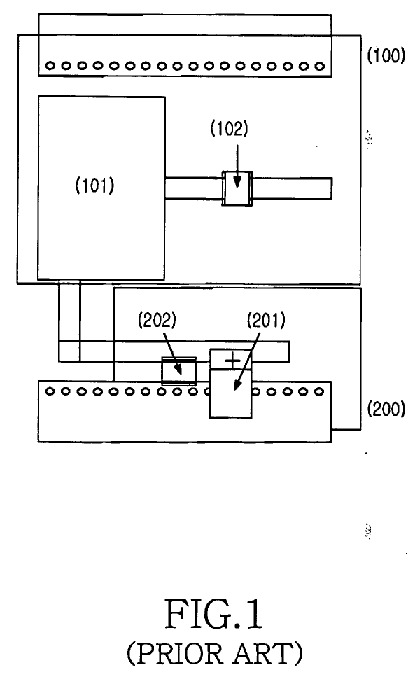

### DETAILED DESCRIPTION OF THE PREFERRED EMBODIMENTS

Preferred embodiments of the present invention will be described herein below with reference to the accompanying drawings. In the following description, well-known functions or constructions are not described in detail since they would obscure the invention in unnecessary detail.

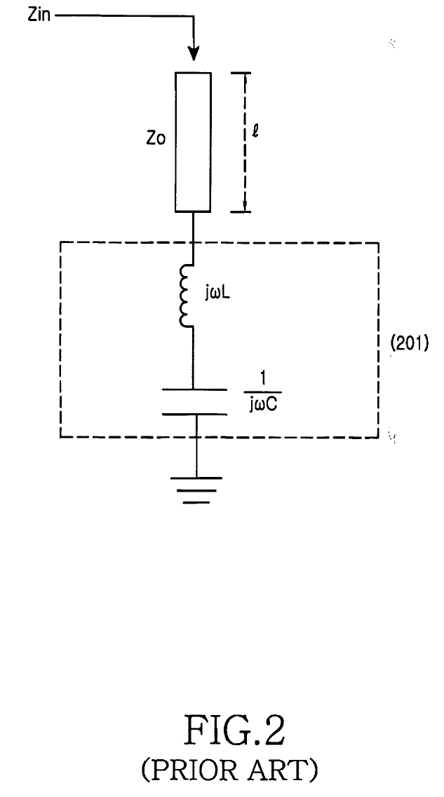

Initially referring to FIG. 2, in a bias circuit designed in the conventional amplifier, there is the impedance of Equation 3, as described in the book written by David M. Pozar, Microwave Engineering, JOHN WILEY & SONS, INC, 1998.
Zin=jZo tan βl+jωL Equation 3:

In Equation 3, Zin is the impedance in view of the matching pattern toward the bias line, j is the imaginary component, Zo is the characteristic impedance of the line, β is the propagation constant, 1 is the length of the bias line, ω is the frequency, and L is the parasitic inductance component in the capacitor.

Since the impedance is close to zero at the low-frequency and high-frequency second harmonic frequencies because of the large capacitor attached for the elimination of the second harmonic, 1/jωC) is close to zero (C is the capacitance value.)

In conclusion, in the conventional power amplifier design method, the impedance at the second harmonic low-frequency shows the rapid increment to tan (β1) function tracking 1. This implies the generation of greater harmonic voltage. The impedance increment can be blocked to some degree by increasing the width of the bias line and decreasing the characteristic impedance (Zo) of the line. Yet, the conventional method is not preferable because the size of the amplifier is extremely enlarged.

Therefore, according to the present invention, by adopting the method of reducing the harmonic voltage by decreasing the 1 value, an additional capacitor is connected directly to the matching circuit to shorten the length of the bias line.

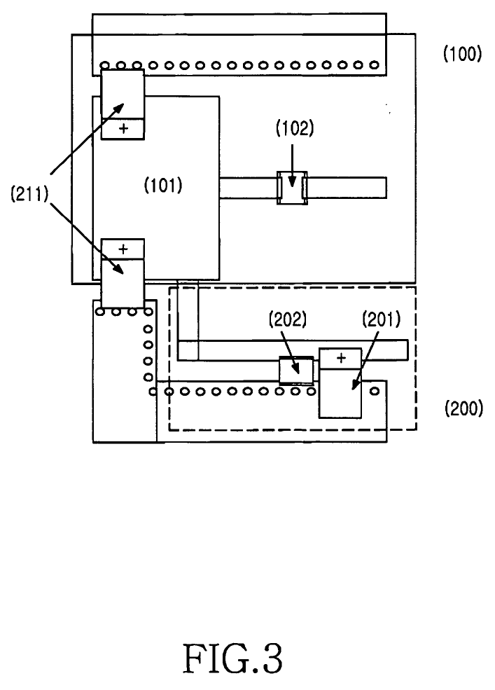

The present invention pertains to a base station power amplifier, which minimizes the memory effect, which will be explained in reference to FIGS. 3 through 8.

FIG. 3 illustrates the base station power amplifier, which minimizes the memory effect according to the present invention. Specifically, FIG. 3 depicts a FET (Field Effect Transistor, which can be a semiconductor device) input circuit or a FET output circuit, with symmetrical structure in the base station power amplifier.

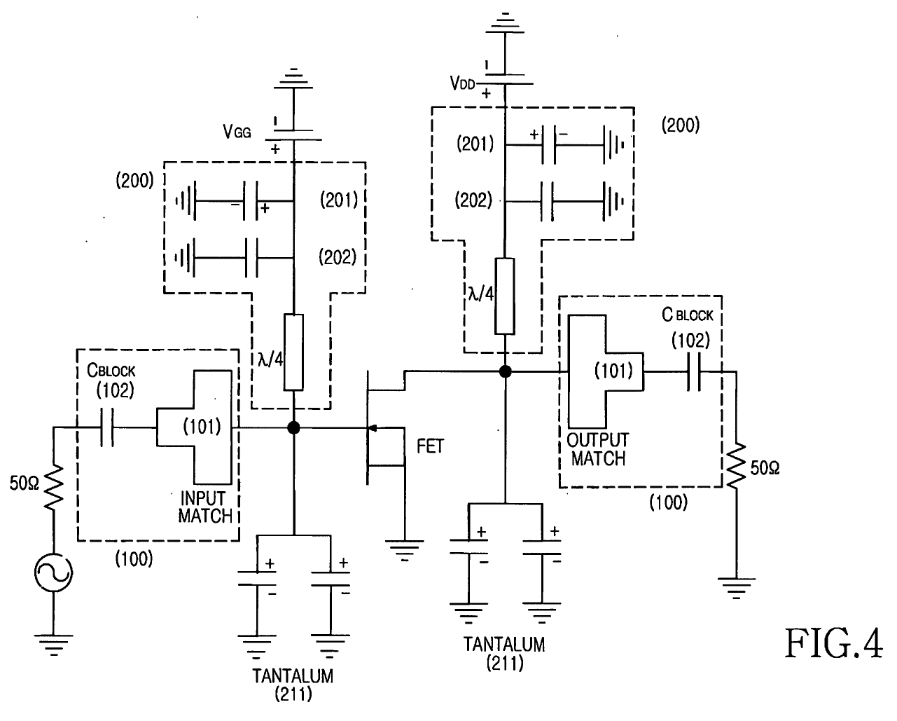

Referring to FIG. 3, the power amplifier of the present invention has the same configuration as the related art, except two large capacitors 211 attached to the start position of a matching circuit 101. Note that this configuration is merely an exemplary embodiment and that there may be provided one or more large capacitors 211. Large capacitor 211 is a Tantalum capacitor having a few to hundreds (μF) of capacitance value, which is further explained following the explanation of FIG. 4.

FIG. 4 is the whole circuit diagram of the base station power amplifier, rather than the model FET(Field Effect Transistor) input circuit or the FET output circuit as shown in FIG. 3. Referring to FIG. 4, the power amplifier circuit has the same structure as the conventional power amplifier, except the large capacitor (Tantalum) 211. FIG. 4 depicts both the FET input circuit and the FET output circuit of FIG. 3, whereas FIG. 3 depicts only one of two circuits because the FET input circuit and the FET output circuit have the symmetrical structure.

Hence, the present invention can greatly reduce the second harmonic voltage limited by the bias line with respect to the broadband signal and thus minimize the memory effect because large capacitor 211 is attached to matching circuit 101 as shown in FIGS. 3 and 4, rather than to the back end of the λ/4 bias line. In general, it seems that the intended signal is not transferred to the final output stage but lost at large capacitor 211 in the configuration of the present invention. However, since all capacitors include the parasitic inductance component to some degree, by resonating the inductance through the appropriate signal matching circuit the signal may not be affected by the capacitor. Thus, the maximum power can be transmitted to the final output stage. In conclusion, the configuration of the present invention can drastically enhance the memory effect of the conventional amplifier, which is generated by the low-frequency second harmonic voltage, and the narrowband characteristic while retaining the maximum power transmission of the related art.

More specifically, large capacitor 211 of the present invention improves the narrowband characteristic of the conventional power amplifier by removing the components K₂_{_{gm}}·v_{gs}(W₂)·v_{gs}(w₂-w₁), K₂_{_{go}}·v₂_{_{ds}}(w₂) ·v_{ds}(w₂-w₁) K₂_{_{gm&go}}·v_{gs}(w₁)·v_{ds}(w₂-w₁), and K ₂_{_{gm&go}}·v_{ds}(w₁)·v_{gs}(w₂-w₁) from the components of Equation 2 which expresses the IMD3 signal.

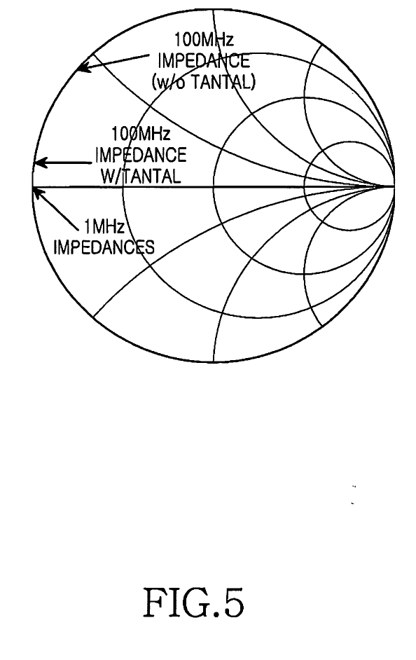

Now, the impedance change of the low-frequency second harmonic component according to the signal bandwidth of the conventional power amplifier and the power amplifier of the present invention is described in reference to FIG. 5.

Since the voltage is proportional to the impedance, the smaller impedance value, the smaller voltage. The main cause of the memory effect is the low-frequency second harmonic voltage. Since the voltage is proportional to the impedance, the smaller low-frequency second harmonic impedance value, the less memory effect. Both the conventional power amplifier and the power amplifier of the present invention have the impedance close to zero with respect to a signal of 1 MHz bandwidth, and this implies little memory effect. However, as the signal bandwidth increases, the conventional amplifier produces the rapid impedance increment for the low-frequency second harmonic, whereas the amplifier of the present invention produces the relatively low impedance increment. This is because of the difference by λ/4 of the bias circuit. As the bandwidth (Δf) increases, the electrical length in view of the low-frequency second harmonic is relatively extended by Δf times.

To predict the memory effect for the broadband signal and the non-linear characteristic of the amplifier, test is generally conducted by applying various 2-tone signals having different tone intervals to the amplifier. One can conclude from the result of the 2-tone test that there is little memory effect as the levels of the right and left IMD signals are similar and kept similar according to the tone intervals. In addition, the linear operation of the amplifier can be ascertained from how low the level is generated.

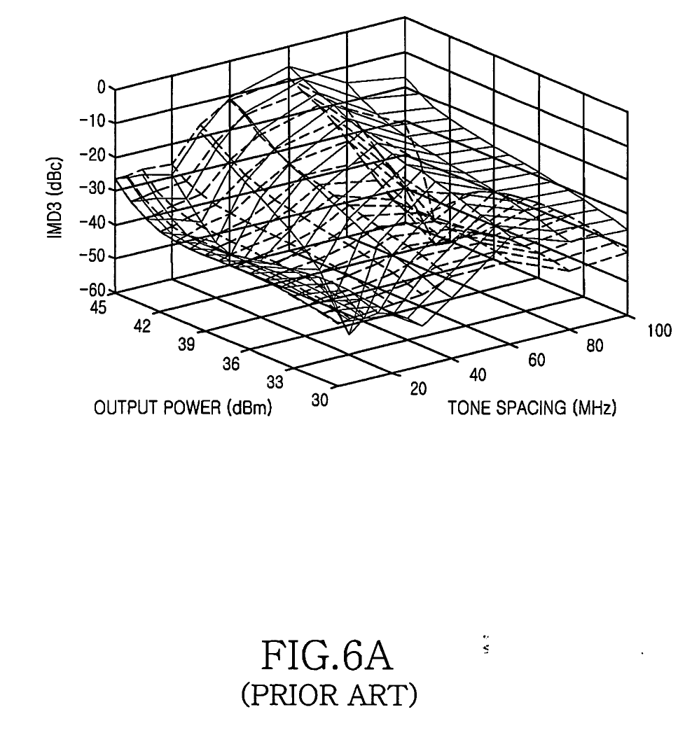

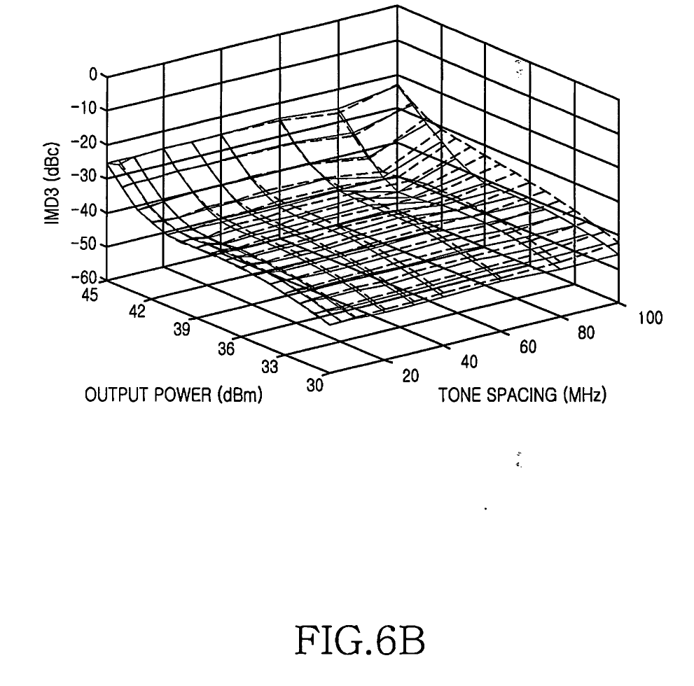

Hereafter, the IMD3 non-linear characteristic of the conventional power amplifier and the power amplifier of the present invention is described by referring to FIGS. 6A and 6B.

FIG. 6A illustrates IMD3 non-linear characteristic when a 2-tone signal is applied to the conventional power amplifier.

FIG. 6B illustrates IMD3 non-linear characteristic when a 2-tone signal is applied to the power amplifier configured according to the present invention.

FIG. 6A shows the right (solid line) and left (dotted line) IMD3 non-linear characteristic when the 2-tone signal is applied to the conventional power amplifier fabricated using a 90 watt transistor, and FIG. 6B shows the non-linear characteristic when the low-frequency second harmonic voltage is minimized using the same transistor as in FIG. 6A and large Tantalum capacitor 211 with respect to the power amplifier according to the present invention. As one can see from FIG. 6A and FIG. 6B, the power amplifier configured according to the present invention reduces the memory effect and the non-linearity, compared to the conventional configuration.

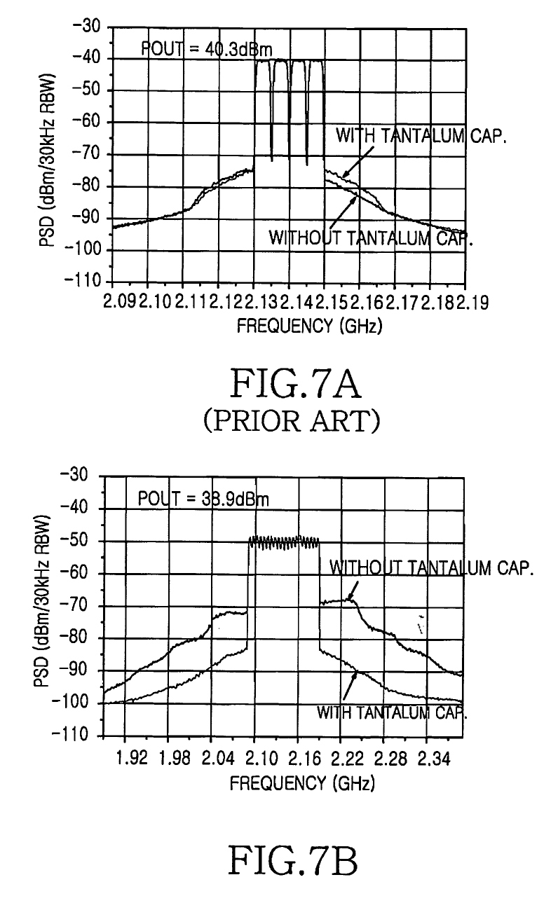

Now, how the IMD3 non-linearity is presented based on the bandwidth in the conventional power amplifier and the power amplifier of the preset invention is described in reference to FIGS. 7A and 7B.

FIG. 7A illustrates output spectrums of the conventional power amplifier and the power amplifier of the present invention at WCDMA 4FA (Frequency assignment) 20 MHz bandwidth signal.

FIG. 7B illustrates output spectrums of the conventional power amplifier and the power amplifier of the present invention at WCDMA 20FA 100 MHz bandwidth signal.

Referring to FIG. 7A, while the conventional power amplifier and the power amplifier of the present invention show similar linearity, the conventional power amplifier exhibits the asymmetric right and left signal spectrums imbalance because of the memory effect. This asymmetry degrades the performance of the linearity enhancement (non-linearity suppression) when the predistortion linearizer is attached.

Referring to FIG. 7B, the power amplifier of the present invention exhibits little performance degradation with respect to the broadband signal.

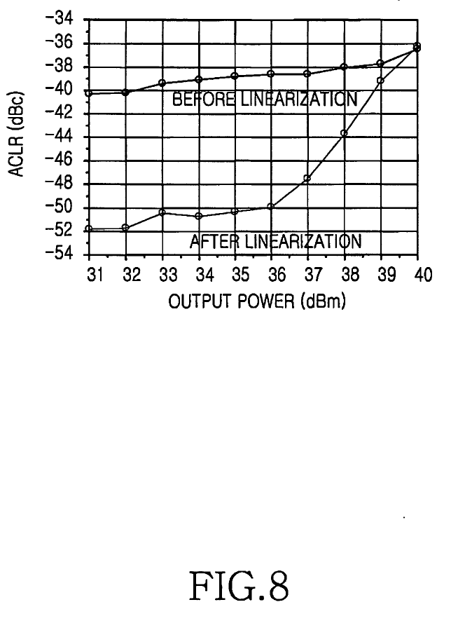

In the following, with reference to FIG. 8 descriptions explaining the linearization performance of the conventional power amplifier and the power amplifier of the present invention when the predistortion linearizer is attached are set forth.

FIG. 8 shows the linearization performance when the predistortion linearizer is attached to the power amplifier of the present invention with respect to the spectrum of FIG. 7(A). The conventional power amplifier is not represented in the graph because it exhibits little difference before and after the linearization. One can see that the power amplifier of the present invention acquires the enhanced linearization performance thanks to the reduced memory effect.

In light of the above, the power amplifier according to the present invention linearly amplifies the broadband signal by minimizing the memory effect of the mobile communication base station/repeater linear power amplifier.

While the invention has been shown and described with reference to certain preferred embodiments thereof, it will be understood by those skilled in the art that various changes in form and details may be made therein without departing from the spirit and scope of the invention as further defined by the appended claims.

What is claimed is:

1. A power amplifier comprising:
a bias circuit which supplies a direct current (DC) power;
a semiconductor device having a gate, the gate receiving the DC power from the bias circuit;
a matching circuit for reducing loss of the power amplified by the device; and
a large capacitor, which lies between a matching circuit and the semiconductor device and has a preset capacitance value.

2. The power amplifier of claim 1, wherein, when there are at least two or more large capacitors, the large capacitors are connected in parallel.

3. The power amplifier of claim 1, wherein the large capacitor reduces memory effect by resonating a parasitic inductance component in the large capacitor and the matching circuit and decreasing a low-frequency second harmonic voltage.

4. The power amplifier of claim 1, wherein the large capacitor eliminates components K₂_{_{gs}}·v_{gs}(w₂)·v_{gs}(w₂-w₁), K₂_{_{go}}·v_{ds}(w₂)·v_{ds}(w₂-w₁) K₂_{_{gm&go}}·v_{gs}(w₁)·v_{ds}(w₂-w₁), and K₂_{_{gm&go}}·v_{ds}(w₁·v_{gs}(w₂-w₁) which are low-frequency second harmonic voltages, from a third order inter-modulation distortion (IMD3) current which is generated at the device and expressed as
$$\begin{matrix}{i}_{d} ( 2 {w}_{2} - {w}_{1} ) = {g}_{m} \cdot {v}_{gs} ( 2 {w}_{2} - {w}_{1} ) + \\ {K}_{{2}_{gm}} \cdot {v}_{gs} ( {w}_{1} ) \cdot {v}_{gs} ( 2 {w}_{2} ) + \\ {K}_{{2}_{gm}} \cdot {v}_{gs} ( {w}_{2} ) \cdot {v}_{gs} ( {w}_{2} - {w}_{1} ) + \\ 3 / 4 \cdot {K}_{{3}_{gm}} \cdot {v}_{gs} ( {w}_{1} ) \cdot {v}_{gs}^{2} ( {w}_{2} ) + \\ {g}_{o} \cdot {v}_{ds} ( 2 {w}_{2} - {w}_{1} ) + \\ {K}_{{2}_{go}} \cdot {v}_{ds} ( {w}_{1} ) \cdot {v}_{ds} ( 2 {w}_{2} ) + \\ {K}_{{2}_{go}} \cdot {v}_{ds} ( {w}_{2} ) \cdot {v}_{ds} ( {w}_{2} - {w}_{1} ) + \\ 3 / 4 \cdot {K}_{{3}_{go}} \cdot {v}_{ds} ( {w}_{1} ) \cdot {v}_{ds}^{2} ( {w}_{2} ) + \\ {K}_{{2}_{gm \& go}} \cdot {v}_{gs} ( {w}_{1} ) \cdot {v}_{ds} ( 2 {w}_{2} ) + \\ {K}_{{2}_{gm \& go}} \cdot {v}_{ds} ( {w}_{1} ) \cdot {v}_{gs} ( 2 {w}_{2} ) + \\ {K}_{{2}_{gm \& go}} \cdot {v}_{gs} ( {w}_{1} ) \cdot {v}_{ds} ( {w}_{2} - {w}_{1} ) + \\ {K}_{{2}_{gm \& go}} \cdot {v}_{ds} ( {w}_{1} ) \cdot {v}_{gs} ( {w}_{2} - {w}_{1} ) + \\ 3 / 4 \cdot {K}_{{3}_{gm \& go}} \cdot {v}_{ds} ( {w}_{1} ) \cdot {v}_{gs}^{2} ( {w}_{2} ) + \\ 3 / 4 \cdot {K}_{{3}_{gm \& 2 go}} \cdot {v}_{gs} ( {w}_{1} ) \cdot {v}_{ds}^{2} ( {w}_{2} )\end{matrix}$$
where v_{gs} is an input voltage, v_{ds} is an output voltage, gₘ, K₂_{_{gm}}, K₃_{_{gm}}, gₒ, K₂_{_{go}}, K₃_{_{go}}, K₂_{_{2gm&go}}, K₃_{_{2gm&go}}, and K₃_{_{gm&2go}} are constants to determine the characteristic of the transistor, and items in parentheses represent frequency components.

5. The power amplifier of claim 1, wherein the power amplifier further comprises an output circuit being connected to a drain of the semiconductor and including a second bias circuit, a second matching circuit, and at least one second capacitor.

6. The power amplifier of claim 1, wherein the large capacitor is a Tantalum capacitor.

7. The power amplifier of claim 1, wherein the semiconductor device is a transistor.

8. A power amplifier comprising:
a semiconductor device;
a bias circuit being coupled and supplying a current to a gate of the transistor;
a matching circuit being coupled to the gate of the semiconductor device and reducing the loss of power amplified by the semiconductor device; and
at least one capacitor being coupled to the gate of the semiconductor device, the matching circuit and the bias circuit wherein the capacity of the capacitor is larger than capacity of other capacitors in the bias circuit.

9. The power amplifier of claim 8, wherein, when there are at least two or more capacitors, the capacitors are connected in parallel.

10. The power amplifier of claim 8, wherein the capacitor reduces memory effect by resonating a parasitic inductance component in the capacitor and the matching circuit and decreasing a low-frequency second harmonic voltage.

11. The power amplifier of claim 8, wherein the capacitor eliminates components K₂_{_{gs}}·v_{gs}(w₂)·v_{gs}(w₂-w₁), K₂_{_{go}}·v_{ds}(w₂)·v_{ds}(w₂-w₁) K₂_{_{gm&go}}·v_{gs}(w₁)·v_{ds}(w₂-w₁), and K₂_{_{gm&go}}·v_{gs}(w₂-w₁) which are low-frequency second harmonic voltages, from a third order inter-modulation distortion (IMD3) current which is generated at the semiconductor device and expressed as
$$\begin{matrix}{i}_{d} ( 2 {w}_{2} - {w}_{1} ) = {g}_{m} \cdot {v}_{gs} ( 2 {w}_{2} - {w}_{1} ) + \\ {K}_{{2}_{gm}} \cdot {v}_{gs} ( {w}_{1} ) \cdot {v}_{gs} ( 2 {w}_{2} ) + \\ {K}_{{2}_{gm}} \cdot {v}_{gs} ( {w}_{2} ) \cdot {v}_{gs} ( {w}_{2} - {w}_{1} ) + \\ 3 / 4 \cdot {K}_{{3}_{gm}} \cdot {v}_{gs} ( {w}_{1} ) \cdot {v}_{gs}^{2} ( {w}_{2} ) + \\ {g}_{o} \cdot {v}_{ds} ( 2 {w}_{2} - {w}_{1} ) + \\ {K}_{{2}_{go}} \cdot {v}_{ds} ( {w}_{1} ) \cdot {v}_{ds} ( 2 {w}_{2} ) + \\ {K}_{{2}_{go}} \cdot {v}_{ds} ( {w}_{2} ) \cdot {v}_{ds} ( {w}_{2} - {w}_{1} ) + \\ 3 / 4 \cdot {K}_{{3}_{go}} \cdot {v}_{ds} ( {w}_{1} ) \cdot {v}_{ds}^{2} ( {w}_{2} ) + \\ {K}_{{2}_{gm \& go}} \cdot {v}_{gs} ( {w}_{1} ) \cdot {v}_{ds} ( 2 {w}_{2} ) + \\ {K}_{{2}_{gm \& go}} \cdot {v}_{ds} ( {w}_{1} ) \cdot {v}_{gs} ( 2 {w}_{2} ) + \\ {K}_{{2}_{gm \& go}} \cdot {v}_{gs} ( {w}_{1} ) \cdot {v}_{ds} ( {w}_{2} - {w}_{1} ) + \\ {K}_{{2}_{gm \& go}} \cdot {v}_{ds} ( {w}_{1} ) \cdot {v}_{gs} ( {w}_{2} - {w}_{1} ) + \\ 3 / 4 \cdot {K}_{{3}_{2 gm \& go}} \cdot {v}_{ds} ( {w}_{1} ) \cdot {v}_{gs}^{2} ( {w}_{2} ) + \\ 3 / 4 \cdot {K}_{{3}_{gm \& 2 go}} \cdot {v}_{gs} ( {w}_{1} ) \cdot {v}_{ds}^{2} ( {w}_{2} )\end{matrix}$$
where v_{gs} is an input voltage, v_{ds} is an output voltage, gₘ, K₂_{_{gm}}, K₃_{_{gm}}, gₒ, K₂_{_{go}}, K₃_{_{go}}, K₂_{_{2gm&go}}, K₃_{_{2gm&go}}, and K₃_{_{gm&2go}} are constants to determine the characteristic of the transistor, and items in parentheses represent frequency components.

12. The power amplifier of claim 8, wherein the power amplifier further comprises an output circuit being connected to a drain of the semiconductor device.

13. The power amplifier of claim 12, wherein the output circuit comprises:
a second bias circuit being coupled a drain of the semiconductor device;
a second matching circuit being coupled to the drain of the semiconductor device; and
at least one second capacitor being coupled to the drain of the semiconductor device, the matching circuit and the bias circuit wherein the capacity of the capacitor is larger than capacity of other capacitors in the second bias circuit.

14. The power amplifier of claim 8, wherein the capacitor is a Tantalum capacitor.

15. The power amplifier of claim 14, wherein Tantalum capacitor has a few to hundreds μF.

16. The power amplifier of claim 13, wherein the second capacitor is a Tantalum capacitor.

17. The power amplifier of claim 15, wherein Tantalum capacitor has a few to hundreds μF.

18. The power amplifier of claim 8, wherein the semiconductor device is a field effect transistor.
